(19) United States
(12) Patent Application Publication
(10) Pub. No.: US 2019/0295878 A1
(43) Pub. Date: Sep. 26, 2019

(54) PUSH-UP DEVICE AND PUSH-UP METHOD FOR A SEMICONDUCTOR DEVICE

(71) Applicant: TOSHIBA MEMORY CORPORATION, Tokyo (JP)

(72) Inventors: Toshimitsu ARAI, Chigasaki Kanagawa (JP); Satoru TAKAKU, Yokohama Kanagawa (JP)

(21) Appl. No.: 16/114,159

(22) Filed: Aug. 27, 2018

(30) Foreign Application Priority Data
Mar. 22, 2018 (JP) 2018-054311

(51) Int. Cl. H01L 21/683; H01L 21/67; H01L 21/687

(52) U.S. Cl. CPC H01L 21/6835; H01L 2221/68386; H01L 21/68742; H01L 21/67092

(57) ABSTRACT

A push-up device for a semiconductor device includes a lifting table which includes a push-up surface, the push-up surface positioned to face a rear surface of an adhesive sheet to push up a semiconductor element bonded to a front surface of the adhesive sheet from the rear surface of the adhesive sheet, and a plurality of convex portions disposed on an outer periphery of the push-up surface of the lifting table to abut corner portions of the semiconductor element through the rear surface of the adhesive sheet when the semiconductor element is pushed up by the lifting table, such that the adhesive sheet peels off from the semiconductor element at locations further outward from the corner portions when the semiconductor element is pushed up by the lifting table.

### CROSS-REFERENCE TO RELATED APPLICATION

This application is based upon and claims the benefit of priority from Japanese Patent Application No. 2018-054311, filed Mar. 22, 2018, the entire contents of which are incorporated herein by reference.

### FIELD

Embodiments described herein relate generally to a push-up device and a push-up method for a semiconductor device.

### BACKGROUND

During an assembly operation of a semiconductor element, a conveyance device peels off a diced semiconductor element (semiconductor chip) from an adhesive sheet and mounts the semiconductor element to a lead frame. In the conveyance device, there is provided a push-up device which pushes up the semiconductor chip.

### DESCRIPTION OF THE DRAWINGS

FIG. 1 is a diagram conceptually illustrating a configuration of a push-up device of a semiconductor device according to an embodiment;

FIG. 2 is a view illustrating an example of an exterior configuration of a lifting block of the push-up device according to the embodiment;

FIG. 3A is a view illustrating an example of an exterior shape of a convex portion which is provided in a first lifting block;

FIG. 3B is a view illustrating an example of a cross-sectional shape of the convex portion which is provided in the first lifting block;

FIG. 4A is a view illustrating an exterior shape of a modification of the convex portion which is provided in the first lifting block;

FIG. 4B is a view illustrating a cross-sectional shape of the modification of the convex portion which is provided in the first lifting block;

FIG. 5 is a view for describing a positional relationship between an outermost lifting block provided in the convex portion and a semiconductor chip;

FIG. 6 is a flowchart for describing an operation of the lifting block of the push-up device according to the embodiment;

FIG. 7A is a view illustrating a standby state of the lifting block of the push-up device according to the embodiment;

FIG. 7B is a view illustrating a peeling state of an adhesive sheet in the semiconductor chip in the standby state according to the embodiment;

FIG. 8A is a view illustrating a first lifting phase of the push-up device;

FIG. 8B is a view illustrating the peeling state of the adhesive sheet with respect to the semiconductor chip during the first lifting phase;

FIG. 9A is a view illustrating a second lifting phase of the push-up device;

FIG. 9B is a view illustrating the peeling state of the adhesive sheet with respect to the semiconductor chip during the second lifting phase;

FIG. 10A is a view illustrating a third lifting phase of the push-up device;

FIG. 10B is a view illustrating the peeling state of the adhesive sheet with respect to the semiconductor chip during the third lifting phase;

FIG. 11A is a view illustrating a fourth lifting phase of the push-up device;

FIG. 11B is a view illustrating the peeling state of the adhesive sheet with respect to the semiconductor chip during the fourth lifting phase;

FIG. 12A is a view illustrating the standby state of the lifting block of the push-up device of the modification of a lifting operation of the lifting block;

FIG. 12B is a view illustrating the first lifting state of the modification in the push-up device;

FIG. 12C is a view illustrating the second lifting state of the modification in the push-up device;

FIG. 12D is a view illustrating the third lifting state of the modification in the push-up device;

FIG. 12E is a view illustrating the fourth lifting state of the modification in the push-up device;

FIG. 13 is a flowchart for describing an operation of the lifting block of the modification of the lifting operation of the lifting block;

FIG. 14 is a view illustrating an exterior shape of a first modification of the convex portion which is provided in the lifting block; and

FIG. 15 is a view illustrating an exterior shape of a second modification of the convex portion which is provided in the lifting block.

### DETAILED DESCRIPTION

Embodiments provide a push-up device and a push-up method for a semiconductor device by which manufacturing accuracy is improved.

In general, according to one embodiment, there is provided a push-up device of a semiconductor device which includes a lifting table which includes a push-up surface, the push-up surface positioned to face a rear surface of an adhesive sheet to push up a semiconductor element bonded to a front surface of the adhesive sheet from the rear surface of the adhesive sheet, and a plurality of convex portions disposed on an outer periphery of the push-up surface of the lifting table to abut corner portions of the semiconductor element through the rear surface of the adhesive sheet when the semiconductor element is pushed up by the lifting table, such that the adhesive sheet peels off from the semiconductor element at locations further outward from the corner portions when the semiconductor element is pushed up by the lifting table.

According to one embodiment, there is provided a method of pushing up a semiconductor device using a lifting table having a plurality of lifting blocks, each of which includes a push-up surface for pushing up a semiconductor element bonded to a front surface of an adhesive sheet from a rear surface of the adhesive sheet. The push-up method includes pushing up corner portions of the semiconductor element using a plurality of convex portions disposed on an outer periphery of the push-up surface of the lifting table to initially peel off the adhesive sheet from the semiconductor element at locations further outward from the corner portions, and sequentially raising or lowering at least two of the lifting blocks after the adhesive sheet is initially peeled off to further peel off the adhesive sheet from an outer side of the semiconductor element toward a center of the semiconductor element.

Hereinafter, an embodiment will be described in detail with reference to the drawings.

### Device Configuration

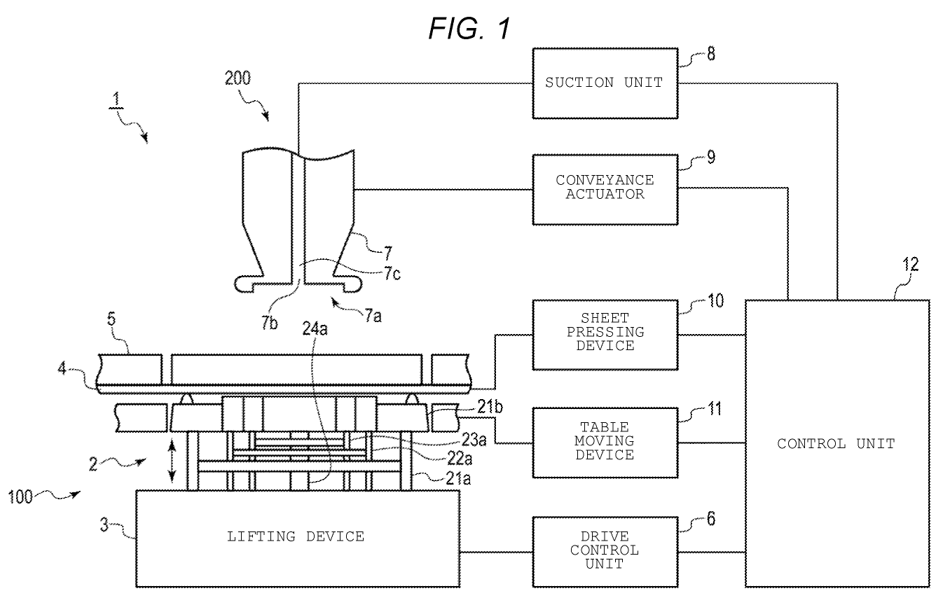

First, a conveyance device including the push-up device of a semiconductor chip will be described with reference FIG. 1 as an example of a device which is used to manufacture the semiconductor device according to the embodiment. In an assembling procedure of the semiconductor device, a semiconductor wafer attached to a dicing device (for example, a dicing tape) is cut by a dicing device, and is separated into a plurality of semiconductor chips on the adhesive sheet. As the dicing tape, for example, an integrated adhesive sheet including a die attach film can also be applied, and may integrally peel off the semiconductor chip and the die attach film from the adhesive sheet. A conveyance device 1 is a so-called pick-up device which peels off each of the semiconductor chips from the adhesive sheet, and mounts the chip to a lead frame.

Generally, the conveyance device 1 includes a push-up device 100 and a conveyance mechanism 200.

The push-up device 100 pushes a semiconductor chip 5 up from an adhesive sheet 4 to peel off a part from the adhesive sheet 4. The conveyance mechanism 200 adsorbs the pushed-up semiconductor chip 5, and conveys the chip onto a target position (for example, the lead frame).

The push-up device 100 includes the lifting table 2, a lifting device 3, a drive control unit 6, a sheet pressing device 10, and a table moving device 11. The lifting table 2 pushes up the semiconductor chip 5 from the adhesive sheet 4. The lifting device 3 individually elevates a plurality of lifting blocks (described below) of the lifting table 2. The drive control unit 6 controls the driving of the lifting device 3. The sheet pressing device 10 applies a tension force to the adhesive sheet 4 which bonds the semiconductor chip 5 on the lifting table 2. The table moving device 11 moves the lifting table 2 to a place immediately below where the semiconductor chip 5 is picked up.

The conveyance mechanism 200 includes a transfer collet 7, a suction unit 8, and a conveyance actuator 9. The transfer collet 7 adsorbs the pushed-up semiconductor chip 5 and picks up the chip to be peeled off from the adhesive sheet 4. The suction unit 8 applies a suction force with which the semiconductor chip 5 is adsorbed to the transfer collet 7. The conveyance actuator 9 moves the adsorbed semiconductor chip 5 to the lead frame (not illustrated) for example.

In addition, a control unit 12 controls the respective portions of the push-up device 100 and the conveyance mechanism 200. Further, the above device configuration is an example configuration in which the lifting table 2 is moved to a place immediately below the designated semiconductor chip 5. However, on the contrary, the designated semiconductor chip 5 may be moved to a place immediately below the lifting table 2 by moving the adhesive sheet 4. In addition, the example below describes a configuration in which the semiconductor chip 5 is pushed up. However, the pushing direction is not limited to the upward direction but, for example, a horizontal direction or a downward direction may be employed.

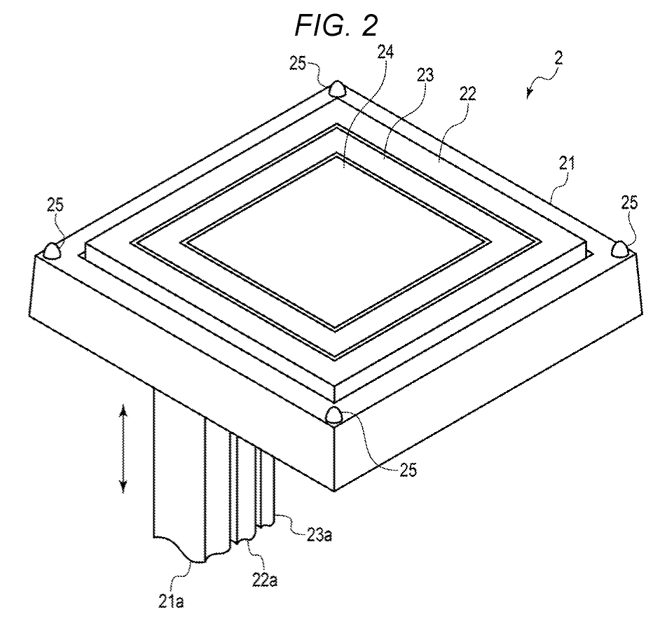

Hereinafter, the respective portions of the conveyance device 1 will be described in detail. First, the configuration of the lifting table 2 and the lifting device 3 will be described with reference to FIGS. 1 and 2.

The lifting table 2 includes a plurality of lifting blocks, each of which elevates. In this embodiment, four lifting blocks 21, 22, 23, and 24 will be given as an example. Frame-shaped lifting blocks 23, 22, and 21 are disposed to face outward in the horizontal direction to encircle the rectangular lifting block 24 which is disposed at the center of the lifting table 2. For example, in a case where the assembled lifting blocks 21, 22, 23, and 24 are disposed about the same center, these blocks are concentrically shaped in a rectangular shape. Of course, the frame shape is not limited to a rectangular shape as long as the lifting blocks are formed of the same frame shape in a magnitude relation, and fitted in a radial direction of the frame. In addition, the number of lifting blocks is not limited to four.

The lifting block 24 is disposed at the center of the table, and includes a push-up surface of a rectangular shape. The lifting block 24 is supported and elevated by a support portion 24a which extends from the lifting device 3.

The lifting block 23 is formed as a rectangular frame shape which surrounds the outer side of the lifting block 24. The lifting block 23 is supported and elevated by a support portion 23a which extends from the lifting device 3. Similarly, the lifting block 22 and the outermost lifting block 21 of the same frame shape are disposed to face and surround the lifting block 23 from the outer side. Even the lifting blocks 21 and 22 are supported and elevated by support portions 21a and 22a extending from the lifting device 3.

As illustrated in FIG. 1, the lifting blocks 22, 23, and 24 of the frame lifting block group are disposed to form a flat table surface by the respective upper surfaces (push-up surfaces). The outermost lifting block 21 is disposed such that the top portion of a convex portion (described below) has the same height as the respective upper surfaces of the lifting blocks 22, 23, and 24. Alternatively, the top portion of the convex portion slightly higher than the respective upper surfaces of the lifting blocks 22, 23, and 24. The lifting table 2 having the layout of the lifting blocks 21, 22, 23, and 24 illustrated in FIG. 1 is in a reference position, and is in a standby state for a push-up operation.

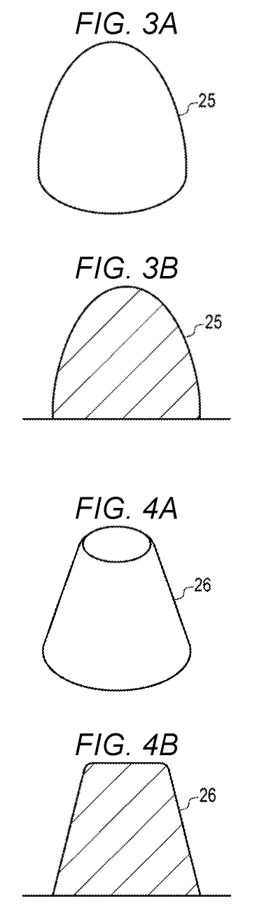

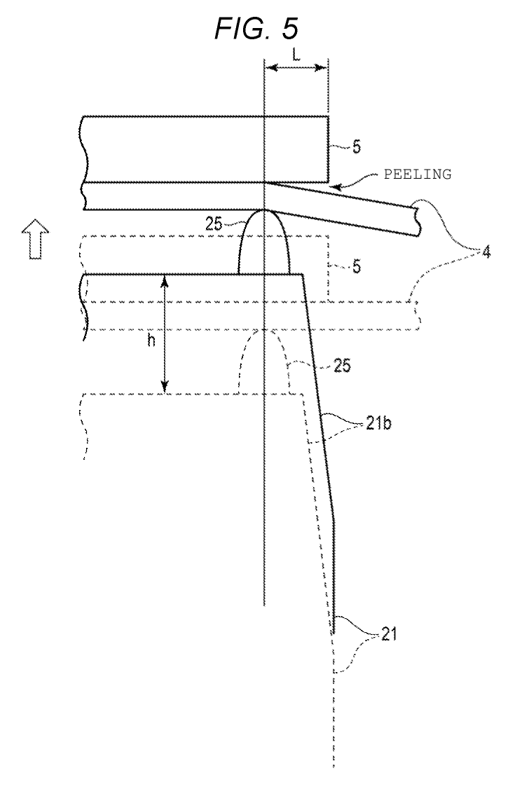

A convex portion 25 is provided at each corner of the lifting table 2, that is, each corner of the upper surface of the lifting block 21 which is disposed on the outermost side. The convex portion 25 is formed in a semispherical shape such as an ellipsoidal shape or a circular shape as illustrated in FIGS. 3A and 3B for example. In addition, as another example, as illustrated in FIGS. 4A and 4B, there maybe formed a convex portion 26 which is formed in a truncated cone and includes a contact surface in the upper portion. Otherwise, a cylindrical shape may be employed, or the upper surface may be a circular flat surface or a rounded spherical shape. Further, the cross-sectional shape maybe a semicircular shape, a semi-ellipsoidal shape, a trapezoidal shape, or a square shape.

In addition, the outermost lifting block 21 is formed such that the shape of at least the upper portion is formed in a square trapezoidal shape. In other words, the side surface on the outer side from the convex portion 25 is inclined to form a slope surface 21b. With the slope surface 21b, the adhesive sheet 4 that is peeled off and inclined downward does not come into contact with the corners of the upper surface of the lifting block 21.

The lifting device 3 individually elevates the lifting blocks 21, 22, 23, and 24 using, for example, a drive source such as a hydraulic actuator and a pneumatic actuator, or a drive source such as a linear motor, an electric motor, and a motor of a link mechanism. The lifting device 3 elevates each of the lifting blocks 21, 22, 23, and 24 by a command of the drive control unit 6 based on a control signal from the control unit 12.

The transfer collet 7 is provided with a suction surface 7a on a leading edge, and is provided with an opening 7b at its inner side. The suction surface 7a is desirably formed to have a surface size similar to a chip size so as to not apply a load locally on the semiconductor chip 5 when the semiconductor chip 5 is peeled off from the adhesive sheet 4. The opening 7b may be formed by one opening in the center of the suction surface 7a, or may be provided by a plurality of openings in a distributed manner on the surface. The opening 7b is connected to the suction unit 8 through a suction passage 7c which passes through the transfer collet 7. As the suction unit 8, for example, a suction pump is used to suck the air in the suction passage 7c of the transfer collet 7, and makes the opening 7b enter into a negative pressure state. The semiconductor chip 5 abuts the opening 7b when adsorbed to the suction surface 7a.

The conveyance actuator 9 includes an arm portion which moves the transfer collet 7 vertically and horizontally. The conveyance actuator 9 positions the suction surface 7a of the transfer collet 7 relative to the semiconductor chip 5 by the control of the control unit 12 so that the semiconductor chip 5 can be adsorbed onto the suction surface 7a. Thereafter, the conveyance actuator 9 moves and transfers the chip by the arm portion to a designated place, for example, the lead frame, and while doing so peels off the adsorbed semiconductor chip 5 from the adhesive sheet 4.

When the lifting table 2 is pushed up, the adhesive sheet 4 starts peeling off from the end portion of the semiconductor chip as described below. The sheet pressing device 10 prevents the adhesive sheet 4 from floating so as to make the semiconductor chip 5 easily peeled off.

In addition, the sheet pressing device 10 may apply tension to make the semiconductor chip 5 easily peeled off from the adhesive sheet 4. The tension may pull both ends of the adhesive sheet 4, and may suck a rear surface side (a non-mounting surface of the semiconductor chip) of the adhesive sheet 4. Alternatively, the adhesive sheet 4 may be not applied with tension as long as the peeling is accelerated by a restoring force (that is, an elastic force or retractility) of the adhesive sheet 4 when the semiconductor chip 5 is pushed up.

Push-up Operation and Conveyance Operation

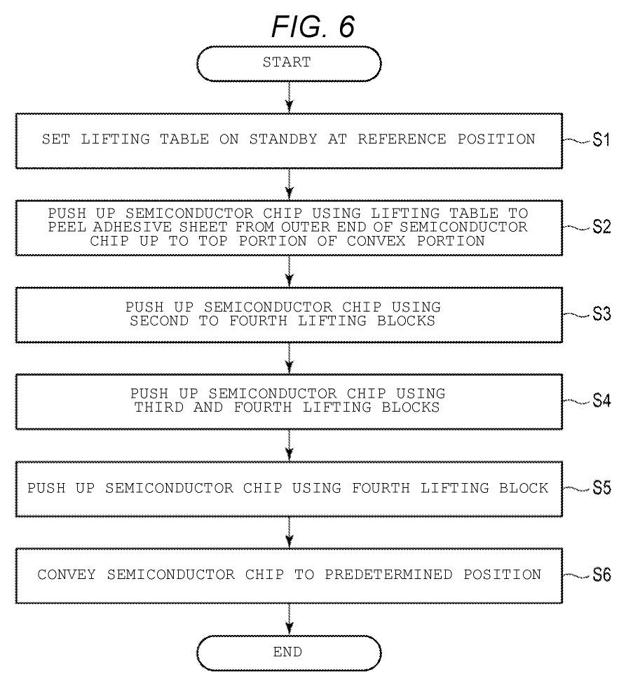

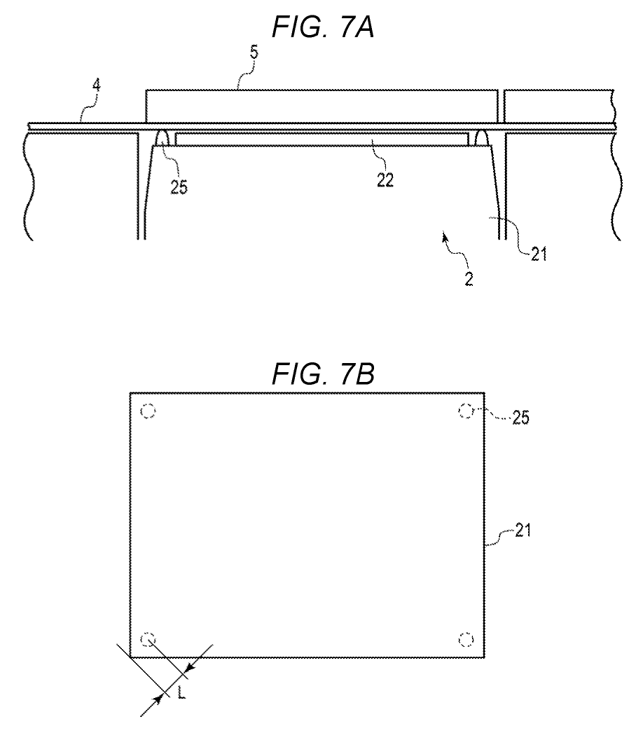

Next, the push-up operation of the convex portion 25 of the lifting block 21 with respect to the semiconductor chip 5 and the peeling of the adhesive sheet 4 will be described with reference to FIGS. 5, 6, 7A and 7B to 11A and 11B. FIG. 6 is a flowchart for describing an operation of the lifting block of the push-up device according to the embodiment. In the following, the description will be given with reference to the flowchart of FIG. 6.

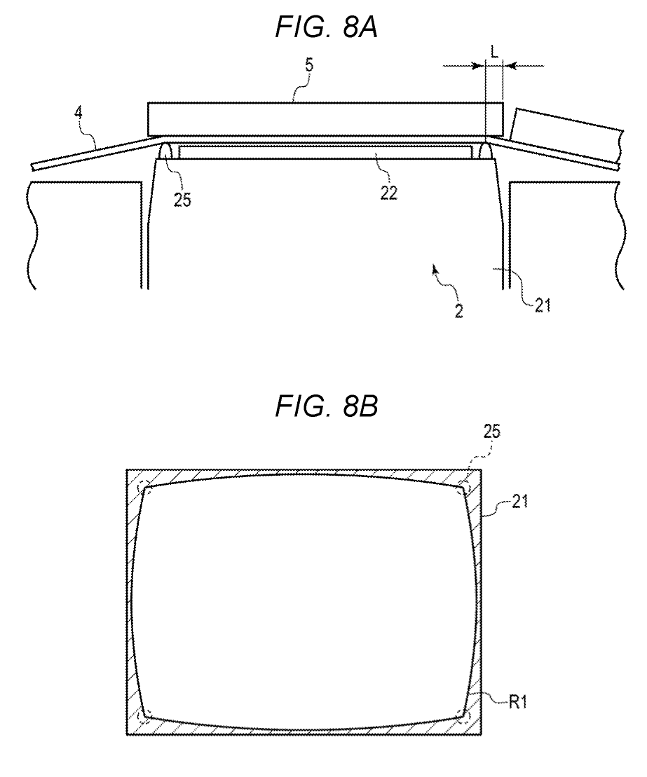

First, as illustrated in FIG. 7A, the lifting table 2 moves to the lower side of the semiconductor chip 5 while being in the standby state at the reference position (Step S1). The standby state herein means a state where the top portion of the convex portion 25 of the lifting block 21 is near the rear surface of the adhesive sheet 4, and the upper surfaces of the lifting blocks 22, 23, and 24 are on standby at the same position or a position slightly lower than the top portion of the convex portion 25 so as not to hinder the movement of the lifting table 2. At this time, as illustrated in FIG. 7B, the rear surface of the semiconductor chip 5 is in a state where the entire surface is bonded to the adhesive sheet 4.

Next, the lifting table 2 rises by a predetermined block projecting amount during a first lifting phase to push up the semiconductor chip 5 (Step S2).

The semiconductor chip 5 is pushed up together with the convex portion 25 of the lifting block 21 by the first lifting of the lifting table 2. In general, a stress in a case where the rectangular semiconductor chip 5 is peeled off from the adhesive sheet 4 is focused on the corners of the chip. Then, the convex portion 25 is provided at the corners of the outermost lifting block 21, and the adhesive sheet 4 is slightly peeled off at the side end (particularly, the corner of the rectangular shape) of the semiconductor chip 5. During this first push-up, the adhesive sheet 4 is slightly peeled off from the corners of the semiconductor chip 5, and the stress on the corner of the chip can be reduced during the next push-up. Then, sequentially, the lifting blocks 22 to 24 are pushed up to move the peeling location of the semiconductor chip 5, and the adhesive sheet 4 is peeled off in a ring shape toward the inside of the chip. Therefore, a partial stress is moved toward the inside of the semiconductor chip 5.

Therefore, when the semiconductor chip 5 is peeled off from the adhesive sheet 4, the generated stress is dispersed in stages and in time series, so that the stressed area moves toward the center of the chip. Therefore, the lifting table 2 according to the embodiment can reduce damage on the end portion and the inner portion of the semiconductor chip 5 unlike a push-up pin of the related art which is pushed up at one time to peel off the semiconductor chip 5 from the adhesive sheet 4.

In addition, when the peeling of the adhesive sheet 4 from the semiconductor chip 5 by the convex portion 25 of the lifting block 21 occurs slightly at the end portion, the peeling location starts to move inside from the corner of the semiconductor chip 5 at the subsequent push-ups. Therefore, it is possible to reduce the stress on the end portion of the semiconductor chip 5. When actually measured, a distance L of the peeled adhesive sheet 4 is about 0<L<0.5 mm from the corner (or the outer peripheral end; the side of the chip) of the semiconductor chip 5 to the top portion of the convex portion 25. Preferably, the adhesive sheet is peeled off by 0.25 mm from the corner of the semiconductor chip 5 to the top portion of the convex portion 25. The distance L is changed in accordance with a thickness of the semiconductor chip 5 and a strength of the silicon substrate.

For example, as illustrated in FIG. 5, in a case where the semiconductor chip 5 and the lifting block 21 are of the same size in area, the top portion of the convex portion 25 may be located within a range of 0<L<0.5 mm from the outer end of the lifting block 21.

In addition, a first rising distance of the lifting table 2 to peel off the semiconductor chip 5 from the adhesive sheet 4, that is, a block projecting amount h of the pushed-up lifting block 21, will be described. As illustrated in FIG. 5, the distance between the side end surface of the semiconductor chip 5 and the top portion of the convex portion 25 is set to “L”, and the blocking projecting amount of the lifting block 21 is set to “h”. As a relation between the distance L and the block projecting amount h obtained by simulation, Ratio (=Block Projecting Amount h/Distance L) may be 0.5 or more and 1.2 or less. Based on the ratio, for example, in a case where the distance L is 0.25 mm, the first block projecting amount h falls within a range of 0.12 mm to 0.3 mm. Of course, these numerical values are changed depending on easiness of the peeling from the adhesive sheet 4, for example, an adhesive strength. The adhesive sheet 4 may be peeled off from the end portion of the semiconductor chip 5 by the convex portion 25 of the lifting block 21 at least during the first push-up.

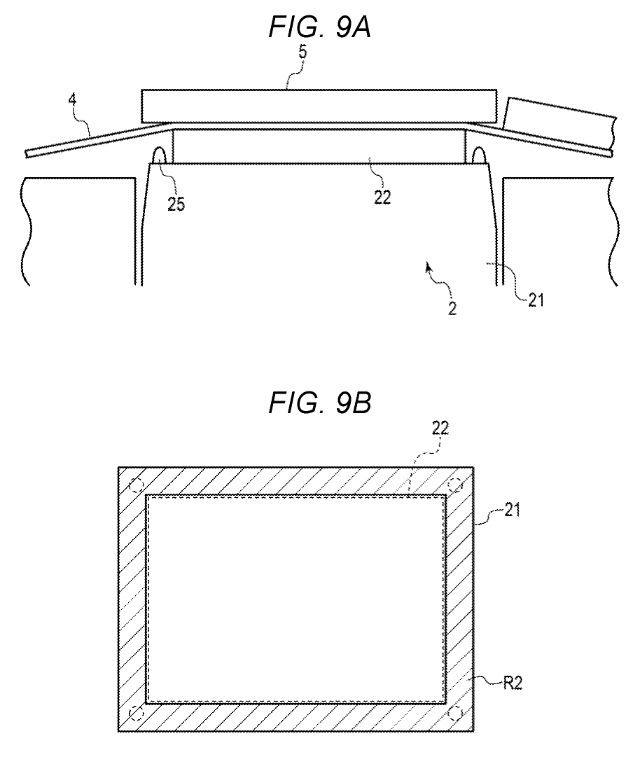

Next, as illustrated in FIG. 8A, the lifting blocks 22, 23, and 24 are raised during a second lifting phase to further push up the semiconductor chip 5 (Step S3). At this time, as illustrated in FIG. 8B, an outer peripheral peeling region R2 of the adhesive sheet 4 corresponding to the push-up surface of the lifting block 21 is peeled off from the semiconductor chip 5.

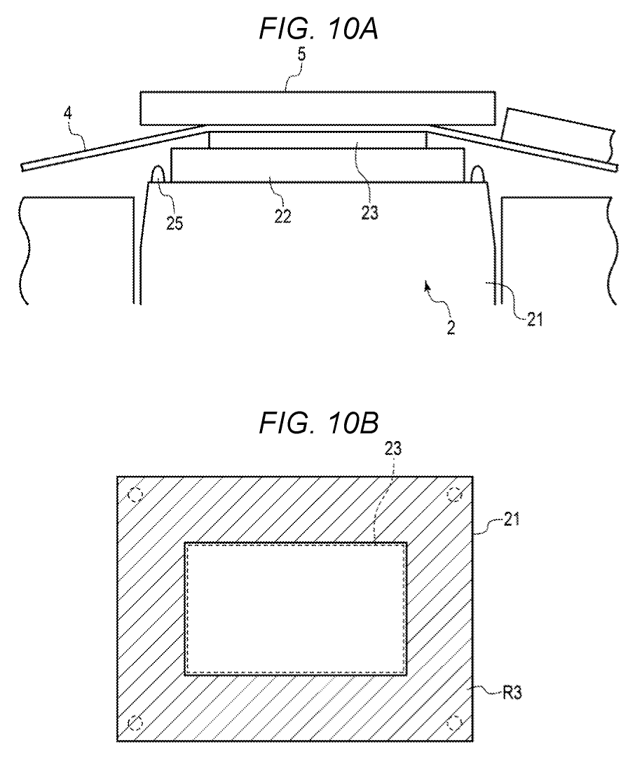

Subsequently, as illustrated in FIG. 9A, the lifting blocks 23 and 24 are further raised to push up the semiconductor chip 5 during a third lifting phase (Step S4). At this time, as illustrated in FIG. 9B, an outer peripheral peeling region R3 corresponding to the push-up surface of the lifting blocks 21 and 22 of the adhesive sheet 4 is peeled off from the semiconductor chip 5.

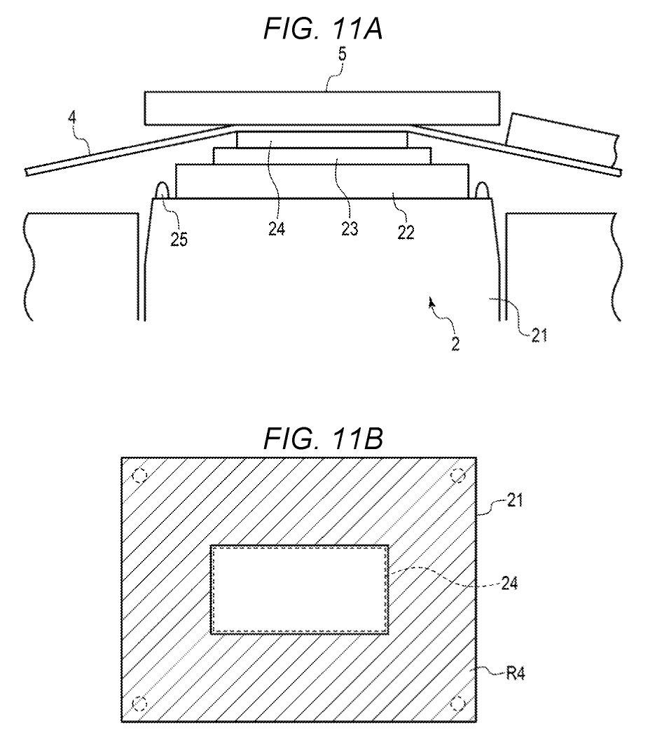

Further, as illustrated in FIG. 10A, the lifting block 24 is further raised to push up the semiconductor chip 5 during a fourth lifting phase (Step S5). At this time, as illustrated in FIG. 10B, an outer peripheral peeling region R4 corresponding to the push-up surface of the lifting blocks 21, 22, and 23 of the adhesive sheet 4 is peeled off from the semiconductor chip 5. In this way, the lifting blocks 21, 22, and 23 are sequentially raised toward an inner side, so that the semiconductor chip 5 is pushed up in stages. The bonding region with the adhesive sheet 4 is reduced to about half when the semiconductor chip 5 is adsorbed onto the transfer collet 7. Further, the peeling region can be appropriately changed by changing a size of the upper surface of the lifting block.

The semiconductor chip 5 pushed up by the lifting block 24 is adsorbed onto the transfer collet 7 to be lifted up, peeled off from the adhesive sheet 4, and conveyed up to a predetermined position (Step S6). Thereafter, the lifting block 24 is lowered, and returns to the standby state illustrated in FIG. 6A together with the lifting blocks 21, 22, and 23.

Operations and Effects of Embodiment

The conveyance device 1 described above first pushes up the semiconductor chip 5, and the adhesive sheet 4 is slightly peeled off from the corners of the semiconductor chip 5 by the convex portion 25 which is provided in the outermost lifting block 21. Thereafter, the semiconductor chip is sequentially pushed up by the push-up surfaces of the lifting blocks 21 to 24 with sequentially reduced pushing areas so as to progress the peeling in stages. Therefore, the semiconductor chip is pushed up using the surfaces of the lifting blocks 21 to 24 while gradually reducing the bonded area of the semiconductor chip 5 and the adhesive sheet 4 over a plurality of times compared to the related art in which the semiconductor chip is pushed up at one time using a pressing pin, so that the stress applied to the semiconductor chip when the adhesive sheet 4 is peeled can be dispersed. Therefore, according to the conveyance device 1, it is possible to avoid breaking and cracking of the outer peripheral end of the semiconductor chip 5, especially in configurations where the outer peripheral end is thinner than that of the semiconductor chip of the related art which does not break even when using the push-up pin.

Further, since the stress is applied over a surface, the stress is not focused on a spot. Therefore, it is possible to prevent cracks in the semiconductor chip 5. With this configuration, after the semiconductor chip 5 is produced as a semiconductor element, it is possible to keep a high-quality performance throughout its product lifetime while avoiding degradation in durability which is caused by inner cracks. In addition, the push-up device according to this embodiment can be applied to various devices, and thus can be used for the existing conveyance device by being replaced with a pick-up mechanism of the push-up pin of the related art.

Modifications of Lifting Operation in Lifting table of Embodiment

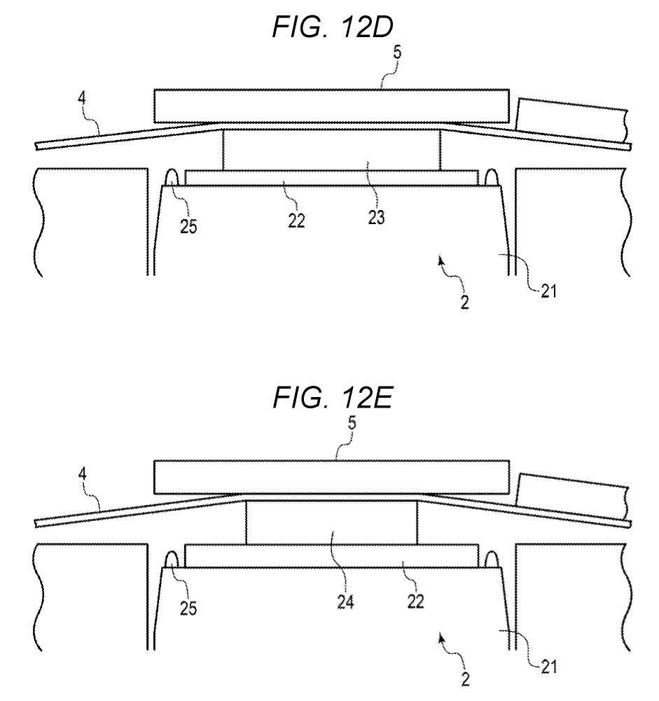

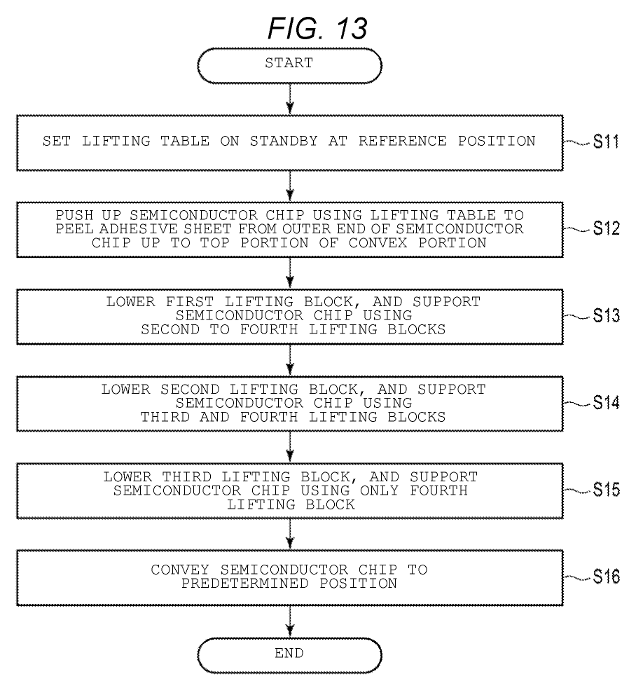

Next, a modification of the lifting operation of the lifting blocks 21 to 24 of the lifting table 2 will be described with reference to FIGS. 12A to 12E. FIG. 13 is a flowchart for describing the operation of the lifting block according to the modification of the lifting operation of the lifting block. The description below will be given with reference to FIG. 13.

First, as illustrated in FIG. 12A, the lifting table 2 moves to the lower side of the semiconductor chip 5 while waiting at the reference position in a standby state (Step S11). The standby state is, similarly to that of the embodiment, a state where only the lifting block 21 is at a position such that the top portion of the convex portion 25 is near but does not abut the rear surface of the adhesive sheet 4, and the lifting blocks 22, 23, and 24 are on standby at positions equal to or slightly below the top portion of the convex portion 25. At this time, as illustrated in FIG. 7B, the rear surface of the semiconductor chip 5 is bonded to the adhesive sheet 4 over the entire surface.

Next, as illustrated in FIG. 12B, the lifting table 2 rises by a predetermined block projecting amount to push up the semiconductor chip 5 during a first lifting phase (Step S12). As illustrated in FIG. 8B, the adhesive sheet 4 is peeled off from the outer end of the semiconductor chip 5 up to the top portion of the convex portion 25 so as to form a peeling region R1. At this time, for example, the adhesive sheet 4 is peeled off by about 0<L<0.5 mm from the outer peripheral end of the semiconductor chip 5 up to the top portion of the convex portion 25. Preferably, the adhesive sheet is peeled off by 0.25 mm from the outer peripheral end of the semiconductor chip 5 up to the top portion of the convex portion 25.

Next, as illustrated in FIG. 12C, only the outermost lifting block 21 is lowered during a second lifting phase. The semiconductor chip 5 keeps the state of being pushed up by the lifting blocks 22, 23, and 24 (Step S13). When the lifting block 21 is lowered, the adhesive sheet 4 is further peeled off up to the lifting block 22 toward the inner side of the semiconductor chip 5 by the tension and the elastic force described above. The outer peripheral peeling region R2 illustrated in FIG. 9B is peeled off.

Next, as illustrated in FIG. 12D, the lifting block 22 is lowered during a third lifting phase. The semiconductor chip 5 keeps the state of being pushed up by the lifting blocks 23 and 24 (Step S14). At this time, the adhesive sheet 4 bonded to the lifting block 22 is peeled off up to the lifting block 23 toward the inner side of the semiconductor chip 5 by the tension and the elastic force described above. The outer peripheral peeling region R3 illustrated in FIG. 10B is peeled off.

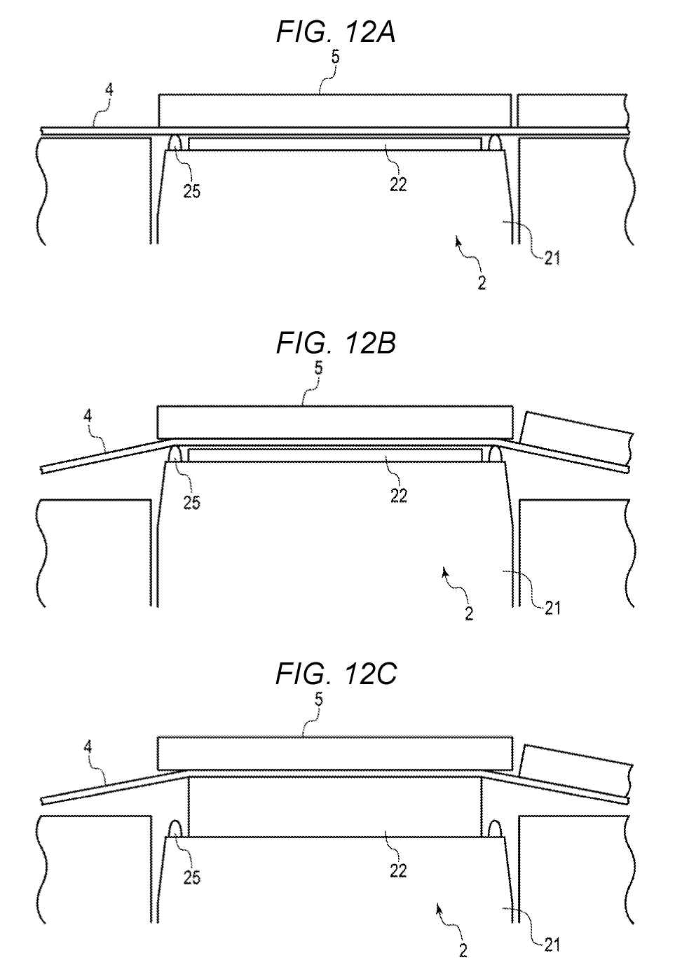

Subsequently, as illustrated in FIG. 12E, the lifting block 23 is lowered during a fourth lifting phase. The semiconductor chip 5 keeps the state of being pushed up only by the lifting block 24 (Step S15). At this time, the adhesive sheet 4 bonded to the lifting block 23 is peeled off up to the lifting block 24 toward the inner side of the semiconductor chip 5. The outer peripheral peeling region R4 illustrated in FIG. 11B is peeled off.

In this example, the outer lifting blocks of the lifting blocks 21, 22, and 23 are sequentially lowered. The bonded area of the semiconductor chip 5 and the adhesive sheet 4 is reduced to the half or less when the semiconductor chip 5 is adsorbed to the transfer collet 7. The semiconductor chip 5 pushed up by the lifting block 24 is adsorbed onto the transfer collet 7, peeled off from the adhesive sheet 4, and conveyed up to a predetermined position (Step S16). Thereafter, the lifting block 24 is lowered, and returns to the standby state illustrated in FIG. 12A.

According to this modification described above, the semiconductor chip 5 is pushed up once, and slightly peeled off from the corners of the semiconductor chip 5 during the first phase. Then, the lifting blocks 21, 22, and 23 are sequentially lowered from the outer side. With these lowering operations, the peeling of the adhesive sheet 4 progresses in stages from the outer side toward the inner side of the semiconductor chip 5. Therefore, in addition to the operational effects of the embodiment, the adhesive sheet 4 can be peeled off in a circular shape from the outer side while keeping a push-up distance less than the case of the peeling by sequentially pushing up the adhesive sheet 4 using the lifting blocks toward the inner side.

First Modification

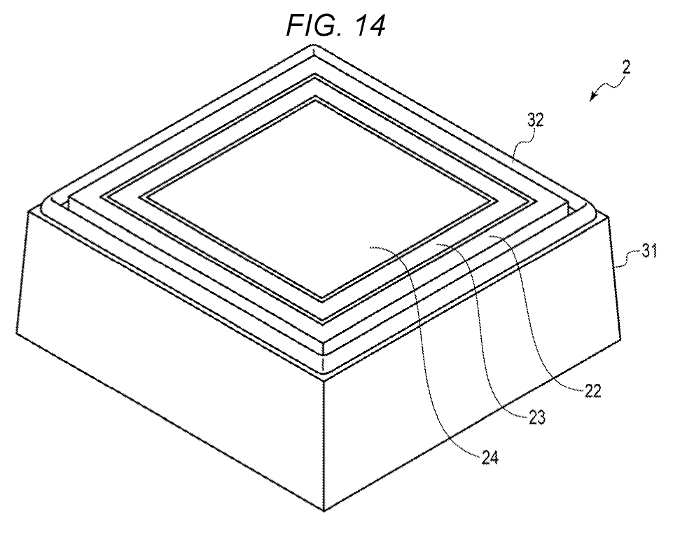

Next, a first modification of the convex portion provided in the lifting block will be described with reference to FIG. 14. This modification is different from the above embodiment only in the shape of the convex portion in the lifting table 2. The same components will be attached with the same symbols, and the detailed description will be omitted.

The first modification is configured such that a convex portion 32 is formed to protrude in an outermost lifting block 31 of the lifting table 2 in a furrow shape or a line shape having no breaks of a rib shape. A cross section of the convex portion 32 may be formed in a semi-ellipsoidal shape or a semicircular shape illustrated in FIG. 3B, or a trapezoidal shape illustrated in FIG. 4B described above.

According to the first modification, the adhesive sheet 4 is peeled off from the corners of the semiconductor chip 5, and a peeling location moves in a side direction of the semiconductor chip 5. In addition, the adhesive sheet 4 may be peeled off up to a side and not only to the corners of the semiconductor chip 5 when being pushed up the first time. In other words, in the next pushing-up, the adhesive sheet 4 starts to be peeled off from the inner side even at the side of the semiconductor chip 5. Therefore, the convex portion 32 of the lifting block 31 comes in linear or narrow-annular contact with the semiconductor chip 5 through the adhesive sheet 4 and pushes up the chip, so that the stress applied to the semiconductor chip 5 during the first phase can be dispersed. Further, even in the next push-up subsequently performed, the adhesive sheet 4 starts peeling off from the inner side rather than from the side end of the semiconductor chip 5. Therefore, it is possible to more securely avoid breaking and cracking in the side end of the semiconductor chip 5.

Second Modification

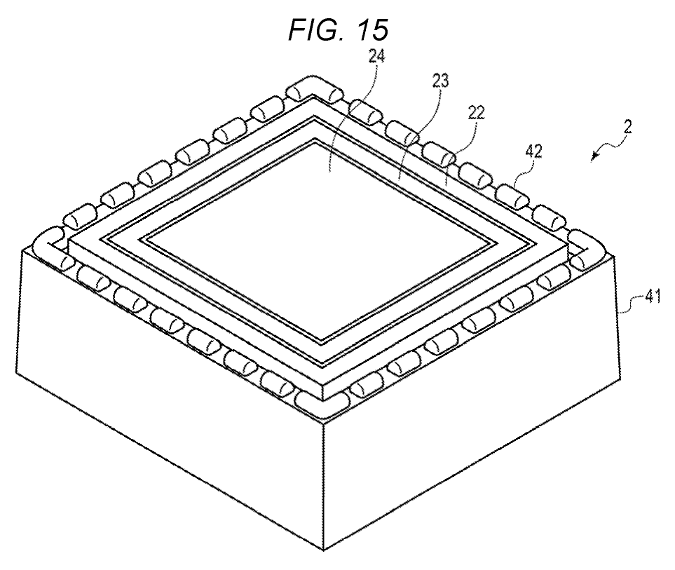

Next, a second modification of the convex portion provided in the lifting block 41 will be described with reference to FIG. 15. This modification is different from the above embodiment only in the shape of the convex portion in the lifting table 2. The same components will be attached with the same symbols, and the detailed description will be omitted. In the second modification, the outermost lifting block 41 of the lifting table 2 is configured such that a plurality of convex portions 42 is disposed in a linear shape. The cross section of the convex portion 42 may be formed in the semi-ellipsoidal shape illustrated in FIG. 3B, or the trapezoidal shape illustrated in FIG. 4B described above.

According to the second modification, the convex portions 42 of the lifting block 41 come in dot-liked contact with the semiconductor chip 5 through the adhesive sheet 4 and push up the chip, so that the stress applied to the semiconductor chip 5 when the adhesive sheet 4 is peeled off can be dispersed compared to the pushing-up of the push-up pin of the related art. In addition, the same effects as those of the first modification can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A push-up device for a semiconductor device, comprising:
a lifting table which includes a push-up surface, the push-up surface positioned to face a rear surface of an adhesive sheet to push up a semiconductor element bonded to a front surface of the adhesive sheet from the rear surface of the adhesive sheet; and
a plurality of convex portions disposed on an outer periphery of the push-up surface of the lifting table to abut corner portions of the semiconductor element through the rear surface of the adhesive sheet when the semiconductor element is pushed up by the lifting table, such that the adhesive sheet peels off from the semiconductor element at locations further outward from the corner portions when the semiconductor element is pushed up by the lifting table.

2. The push-up device according to claim 1, wherein
the lifting table includes a plurality of lifting blocks which has upper surfaces that form the push-up surface, and
the convex portions are formed on at least corners of the lifting block that is on an outermost side.

3. The push-up device according to claim 2, wherein the plurality of lifting blocks includes a center lifting block, and at least one outer lifting block surrounding the center lifting block.

4. The push-up device according to claim 3, wherein the said at least one outer lifting block includes a first outer lifting block surrounding the center lifting block, a second outer lifting block surrounding the first outer lifting block, and a third outer lifting block surrounding the second outer lifting block, the convex portions being disposed on the third outer lifting block.

5. The push-up device according to claim 4, further comprising:
a lifting device configured to elevate the center lifting block and the outer lifting blocks in a plurality of phases, including
a first phase during which the lifting device pushes up the semiconductor element by the convex portions of the third outer lifting block,
a second phase after the first phase, during which the second outer lifting block pushes up the semiconductor element,
a third phase after the second phase, during which the first outer lifting block pushes up the semiconductor element, and
a fourth phase after the third phase, during which the center lifting block pushes up the semiconductor element.

6. The push-up device according to claim 4, further comprising:
a lifting device configured to elevate the center lifting block and the outer lifting blocks in a plurality of phases, including
a first phase during which the lifting device pushes up the semiconductor element by the convex portions of the third outer lifting block,
a second phase after the first phase, during which the third outer lifting block is lowered so that the center lifting block, the first outer lifting block, and the second outer lifting block push up on the semiconductor element,
a third phase after the second phase, during which the second outer lifting block is lowered to no longer push up on the semiconductor element, and
a fourth phase after the third phase, during which the first outer lifting block is lowered to no longer push up on the semiconductor element.

7. The push-up device according to claim 1, wherein
the convex portions have one of a semispherical shape of which a cross section is semi-ellipsoidal or semicircular, a truncated cone shape of which a cross section is trapezoidal, and a cylindrical shape of which a cross section is rectangular.

8. The push-up device according to claim 1, wherein
a distance L between a corner of the semiconductor element and a top portion of the convex portion nearest to said corner, when the semiconductor element is pushed up is 0<L<0.5 mm.

9. The push-up device according to claim 1, wherein
the lifting table is formed in a truncated cone shape of which at least an upper surface forms a slope surface.

10. The push-up device according to claim 1, wherein
the adhesive sheet is an adhesive sheet including a die attach film, and the semiconductor element and the die attach film are peeled off from the adhesive sheet.

11. A push-up method for a semiconductor device using a lifting table having a plurality of lifting blocks, each of which includes a push-up surface for pushing up a semiconductor element bonded to a front surface of an adhesive sheet from a rear surface of the adhesive sheet, comprising:
pushing up corner portions of the semiconductor element using a plurality of convex portions disposed on an outer periphery of the push-up surface of the lifting table to initially peel off the adhesive sheet from the semiconductor element at locations further outward from the corner portions; and
sequentially raising at least two of the lifting blocks after the adhesive sheet is initially peeled off to further peel off the adhesive sheet from an outer side of the semiconductor element toward a center of the semiconductor element.

12. The push-up method according to claim 11, wherein the lifting blocks include a center lifting block, a first outer lifting block surrounding the center lifting block, a second outer lifting block surrounding the first outer lifting block, and a third outer lifting block surrounding the second outer lifting block, the convex portions being disposed on the third outer lifting block.

13. The push-up method according to claim 12, wherein during said sequential raising, the second outer lifting block, the first outer lifting block, and the center lifting block are raised in that order.

14. The push-up method according to claim 11, wherein
the convex portions have one of a semispherical shape of which a cross section is semi-ellipsoidal or semicircular, a truncated cone shape of which a cross section is trapezoidal, and a cylindrical shape of which a cross section is rectangular.

15. The push-up method according to claim 11, wherein
a distance L between a corner of the semiconductor element and a top portion of the convex portion nearest to said corner, when the semiconductor element is pushed up is 0<L<0.5 mm.

16. A push-up method for a semiconductor device using a lifting table having a plurality of lifting blocks, each of which includes a push-up surface for pushing up a semiconductor element bonded to a front surface of an adhesive sheet from a rear surface of the adhesive sheet, comprising:
pushing up corner portions of the semiconductor element using a plurality of convex portions disposed on an outer periphery of the push-up surface of the lifting table to initially peel off the adhesive sheet from the semiconductor element at locations further outward from the corner portions; and
sequentially lowering at least two of the lifting blocks after the adhesive sheet is initially peeled off to further peel off the adhesive sheet from an outer side of the semiconductor element toward a center of the semiconductor element.

17. The push-up method according to claim 16, wherein the lifting blocks include a center lifting block, a first outer lifting block surrounding the center lifting block, a second outer lifting block surrounding the first outer lifting block, and a third outer lifting block surrounding the second outer lifting block, the convex portions being disposed on the third outer lifting block.

18. The push-up method according to claim 17, wherein during said sequential lowering, the third outer lifting block, the second outer lifting block, and the first outer lifting block are lowered in that order.

19. The push-up method according to claim 11, wherein
the convex portions have one of a semispherical shape of which a cross section is semi-ellipsoidal or semicircular, a truncated cone shape of which a cross section is trapezoidal, and a cylindrical shape of which a cross section is rectangular.

20. The push-up method according to claim 11, wherein
a distance L between a corner of the semiconductor element and a top portion of the convex portion nearest to said corner, when the semiconductor element is pushed up is 0<L<0.5 mm.
